(19) United States
(12) Patent Application Publication
(10) Pub. No.: US 2017/0141291 A1
(43) Pub. Date: May 18, 2017

(54) ELECTRONIC DEVICE AND METHOD OF MANUFACTURING THE SAME

(71) Applicant: Commissariat à l'Énergie Atomique et aux Énergies Alternatives, Paris (FR)

(72) Inventors: Abdelkader Aliane, Grenoble (FR); Mohammed Benwadih, Champigny Sur Marne (FR)

(73) Assignee: Commissariat à l'Énergie Atomique et aux Énergies Alternatives, Paris (FR)

(21) Appl. No.: 15/351,555

(22) Filed: Nov. 15, 2016

(30) Foreign Application Priority Data
Nov. 17, 2015 (FR) 15/61045

(51) Int. Cl. H01L 41/08; H01L 41/083; H01L 41/193; C09D 127/16; H01L 41/253; H01L 29/51; H01L 21/02; H01L 21/28; H01L 41/317; H01L 37/02

(52) U.S. Cl. CPC H01L 41/0805; H01L 41/317; H01L 41/083; H01L 41/193; H01L 37/025; H01L 41/253; H01L 29/51; H01L 21/0212; H01L 21/02282; H01L 21/28194; H01L 21/02348; C09D 127/16

(57) ABSTRACT

A method of manufacturing an electronic device including a film, including the steps of forming at least one layer of a solution including a solvent and a compound including a polymer selected from the group including poly(vinylidene fluoride-trifluoroethylene-chlorofluoroethylene) (P(VDF-TrFE-CFE)), poly(vinylidene fluoride-trifluoroethylene-chlorotrifluoroethylene) (P(VDF-TrFE-CTFE)) and a mixture of these compounds, the molecular rate of chlorine in the copolymer being greater than or equal to 3%; and irradiating at least the layer with pulses of at least one ultraviolet radiation.

This application claims the priority benefit of French patent application number 15/61045, filed Nov. 17, 2015, which is hereby incorporated by reference in its entirety to the maximum extent allowable by law.

### BACKGROUND

The present disclosure relates to a method of manufacturing an electronic device comprising a film of a copolymer of polyvinylidene fluoride (PVDF) and to an electronic device obtained by such a method.

### DISCUSSION OF THE RELATED ART

It is known to form an electronic device comprising a film of a PVDF copolymer. According to an example, the electronic device corresponds to a metal-oxide gate field effect transistor, also called MOS transistor, the film of the PVDF copolymer forming the gate insulator of the transistor. According to another example, the electronic device corresponds to a pyroelectric and/or piezoelectric device capable of being used as a sensor, for example, as a pressure sensor, as a switch, or as an energy recovery device.

PVDF copolymers are semi-crystal polymers which, after the polymerization step, have a volume crystallinity generally in the range from 45% to 55%. The PVDF copolymer may comprise crystal phases of three types, α, β, and γ. After the polymerization step, the obtained crystal phase generally mainly is the a phase. The electric insulation properties of the obtained film are generally not adapted to a use as a gate insulator of a MOS transistor. Further, the β phase may have pyroelectric and piezoelectric properties while the a phase does not. Thereby, the film obtained after polymerization is not adapted to a use in a pyroelectric and/or piezoelectric device.

An additional treatment may also generally be provided to at least partly transform the α phase into a β phase, which provides the desired electric insulation properties, pyroelectric properties, and/or piezoelectric properties. The treatment may further cause an increase in the degree of crystallinity of the film.

The treatment may comprise:
a thermal anneal, for example, at a temperature in the range from 110° C. to 170° C. for a time period varying from several minutes to several hours;
applying to the film an electric field of high intensity for several hours; and/or
ionizing the air around the PVDF copolymer film.

It may be desirable to form the PVDF copolymer film on a substrate of a plastic material, for example, polyethylene naphthalate (PEN) or polyethylene terephthalate (PET). It may further be desirable to form the PVDF copolymer film on a substrate also having other electronic components formed thereon or therein.

A disadvantage of previously-described treatments is that they may be incompatible with the use of a plastic substrate or with the forming of electronic components, particularly due to the high temperatures and/or mechanical stress applied. Another disadvantage of treatments of mechanical polymer stretching, electric field application, or air ionization is that they may be complex to implement, particularly at an industrial scale. Another disadvantage of thermal anneal and electric field application treatments is that they may have a significant duration.

### SUMMARY

An embodiment aims at overcoming the disadvantages of previously-described electronic device manufacturing methods.

Another embodiment aims at manufacturing an electronic device comprising a film of a PVDF copolymer on a plastic substrate.

Another embodiment aims at the manufacturing of an electronic device comprising a PVDF copolymer film on a substrate also having other electronic components formed thereon or therein.

Another embodiment aims at decreasing the duration of the method of manufacturing an electronic device comprising a film of a PVDF copolymer.

Another embodiment aims at a manufacturing method capable of being implemented at an industrial scale.

Thus, an embodiment provides a method of manufacturing an electronic device comprising a film, comprising the steps of:
forming at least one layer of a solution comprising a solvent and a compound comprising a polymer selected from the group comprising poly(vinylidene fluoride-trifluoroethylene-chlorofluoroethylene), poly(vinylidene fluoride-trifluoro-ethylene-chlorotrifluoroethylene) and a mixture of these compounds, the molecular rate of chlorine in the copolymer being greater than or equal to 3%; and
irradiating at least the layer with pulses of at least one ultraviolet radiation.

According to an embodiment, the ultraviolet radiation is emitted by a source, said layer comprising a surface exposed to ultraviolet radiation and the distance between said surface and the source is in the range from 2 cm to 10 cm.

According to an embodiment, the duration of each pulse is in the range from 500 μs to 2 ms.

According to an embodiment, the energy fluence of the ultraviolet radiation is in the range from 10 J/cm² to 25 J/cm².

According to an embodiment, only a portion of the layer is heated during the irradiation step.

According to an embodiment, the irradiation step is followed by a step of thermal anneal of the rest of the layer at a temperature in the range from 80° C. to 120° C.

According to an embodiment, the solvent has an evaporation temperature in the range from 110° C. to 140° C.

According to an embodiment, the solution comprises from 80 wt. % to 95 wt. % of the solvent and from 5 wt. % to 20 wt. % of the compound.

According to an embodiment, the solvent is capable of at least partially absorbing the ultraviolet radiation.

According to an embodiment, the compound further comprises ceramic particles.

An embodiment also provides a piezoelectric and/or pyroelectric device comprising a layer mainly comprising a partly crystallized polymer selected from the group comprising poly(vinylidene fluoride-trifluoroethylene-chlorofluoro-ethylene), poly(vinylidene fluoride-trifluoroethylene-chlorotrifluoroethylene) and a mixture of these compounds, the molecular rate of chlorine in the copolymer being greater than or equal to 3%, wherein on at least part of the thickness of the layer, the crystal phase(s) of the polymer have the same crystal orientation.

According to an embodiment, the layer comprises first crystallized sub-layer of said polymer where the crystal phase(s) of the polymer have the same crystal orientation and a second sub-layer of said polymer covered with the first sub-layer and in contact with the first sub-layer where the crystal phase(s) of the polymer have different crystal orientations.

The foregoing and other features and advantages will be discussed in detail in the following non-limiting description of specific embodiments in connection with the accompanying drawings.

### BRIEF DESCRIPTION OF THE DRAWINGS

FIGS. 1 and 2 show X-ray diffraction diagrams respectively obtained for films of a PVDF copolymer respectively formed according to a conventional manufacturing method and according to an embodiment of a manufacturing method;

FIG. 3 shows curves of the variation of the relative dielectric permittivity of films of a PVDF copolymer, respectively formed according to a conventional manufacturing method and according to an embodiment of a manufacturing method, according to the frequency of the voltage applied to the film;

FIG. 4 shows curves of the variation of the displacements of films of a PVDF copolymer, respectively formed according to a conventional manufacturing method and according to an embodiment of a manufacturing method, according to the voltage applied to the film;

FIGS. 5A to 5E are partial simplified cross-section views of the structures obtained at successive steps of another embodiment of a method of manufacturing a MOS transistor comprising a film of a PVDF copolymer; and

FIGS. 6A to 6D are partial simplified cross-section views of the structures obtained at successive steps of an embodiment of a pyroelectric/piezoelectric device comprising a film of a PVDF copolymer.

### DETAILED DESCRIPTION

For clarity, the same elements have been designated with the same reference numerals in the various drawings and, further, as usual in the representation of electronic circuits, the various drawings are not to scale. Further, only those elements which are useful to the understanding of the present description have been shown and will be described. Unless otherwise specified, expressions “approximately”, “substantially”, and “in the order of” mean to within 10%, preferably to within 5%.

The inventors have shown that by selecting specific PVDF copolymers and by applying a specific thermal treatment thereto, a film of PVDF copolymer having significant piezoelectric and/or pyroelectric properties and/or a high dielectric constant is obtained.

The PVDF copolymer comprises poly(vinylidene fluoride-trifluoroethylene-chlorofluoroethylene) (P(VDF-TrFE-CFE)), poly(vinylidene fluoride-trifluoroethylene-chlorotrifluoro ethylene) (P(VDF-TrFE-CTFE)) or a mixture of these compounds. The chlorine molecule rate of the copolymer is greater than or equal to 3%, preferably greater than or equal to 4%.

According to an embodiment, the thermal treatment comprises applying short pulses of an ultraviolet radiation (UV) or ultraviolet flashes on a liquid layer mainly comprising the PVDF copolymer. This enables to heat the liquid phase to favor the forming of the β crystal phase. This enables to locally heat the liquid layer without heating the substrate having the layer comprising the PVDF copolymer formed thereon and/or without heating electronic components close to the film of PVDF copolymer. A film of the PVDF copolymer having desired properties is thus obtained.

UV radiation means a radiation having wavelengths at least partly in the range from 200 nm to 400 nm. The UV radiation may be supplied by a lamp, for example, a Xenon lamp, which may supply a radiation which extends over a wavelength range wider than the range from 200 nm to 400 nm, for example, over the range from 150 nm to 1,000 nm. The distance between the UV pulse emission source and the surface of the layer mainly comprising the PVDF copolymer is in the range from 2 cm to 10 cm. According to an embodiment, the duration of a UV pulse is in the range from 10 μs to 5 ms, preferably from 500 μs to 2 ms. The duration between two successive UV pulses may be in the range from 1 to 5 seconds. The fluence of the (UV) radiation may be in the range from 1 J/cm² to 100 J/cm², preferably from 10 J/cm² to 25 J/cm². The number of pulses is in the range from 1 to 100.

Tests have been carried out to compare the properties of a film of a PVDF copolymer, called comparison film hereafter, obtained by a manufacturing method comprising a step of thermal anneal by a long-term heating of the film, with the properties of a film of a PVDF copolymer, called test film hereafter, obtained by a manufacturing method comprising a UV pulse application step.

The comparison film and the test film have each been obtained from a liquid 2-μm thick layer formed by silk-screening deposition of a solution comprising 20 wt. % of the P(VDF60-TrFe30,3-CTFE9,7) copolymer and 80 wt. % of cyclopentanone. The molar rate or molecular rate of chlorine in P(VDF60-^{TrFe}30,3-^{CTFE}9,7) is 9.7%. The solution has been obtained by mixing 2 g of cyclopentanone and 0.4 g of a P(VDF60-TrFe30,3-CTFE9,7) powder at a temperature in the range from 40 to 45° C. for several hours. For the comparison film, the layer has been heated on a hot plate at 130° C. for 15 minutes. For the test film, the layer has been irradiated by 20 UV pulses supplied by a UV lamp having a radiation over a wavelength range which extends from 240 nm to 1,000 nm, with more than 75% of the energy between 240 nm and 400 nm. The duration of each pulse is 2 ms. The duration between two successive pulses is 1 second. The energy fluence of the UV radiation is 21 J/cm². The distance between the UV lamp and the upper surface of the PVDF copolymer layer is 4.5 cm.

FIG. 1 shows an X-ray diffraction diagram of the comparison film. Curve C1 comprises a plurality of crystallization peaks, particularly a peak P1 for an angle 2θ1 substantially equal to 18°, a peak P2 of greater intensity for an angle 2θ2 substantially equal to 22°, a peak P3 of decreased intensity for an angle 2θ3 substantially equal to 34°, and additional peaks at angles 2θ greater than 2θ3 and at lower intensities. This reflects the presence of β crystal phases in the comparison film having different crystal orientations.

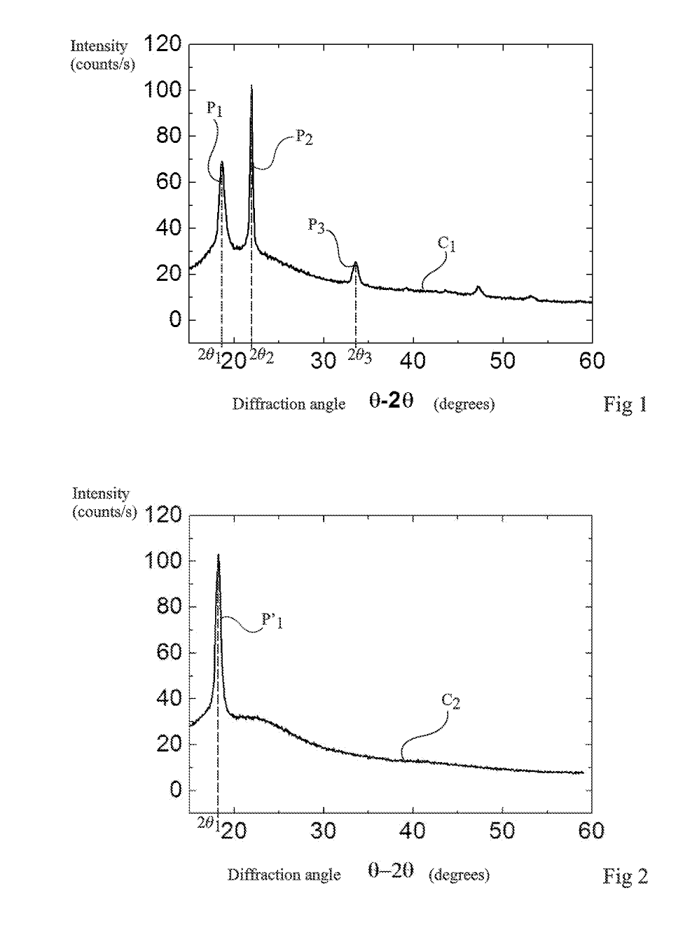

FIG. 2 shows an X-ray diffraction diagram of the test film. Curve C2 comprises a single peak P′1 for angle 201 substantially equal to 18°. This reflects the presence of a β crystal phase in the test film having a single crystal orientation. The degree of crystallinity of the comparison film is greater than the degree of crystallinity of the test film.

The inventors have shown that for the other PVDF copolymers other than the polymers of the group comprising P(VDF-TrFE-CFE), P(VDF-TrFE-CTFE), or a mixture of these compounds, the X-ray diffraction diagram of the test film is substantially identical to the X-ray diffraction diagram of the test film.

The inventors have highlighted an increase in the relative dielectric permittivity εr with respect to vacuum, also called dielectric constant, of the test film with respect to the comparison film.

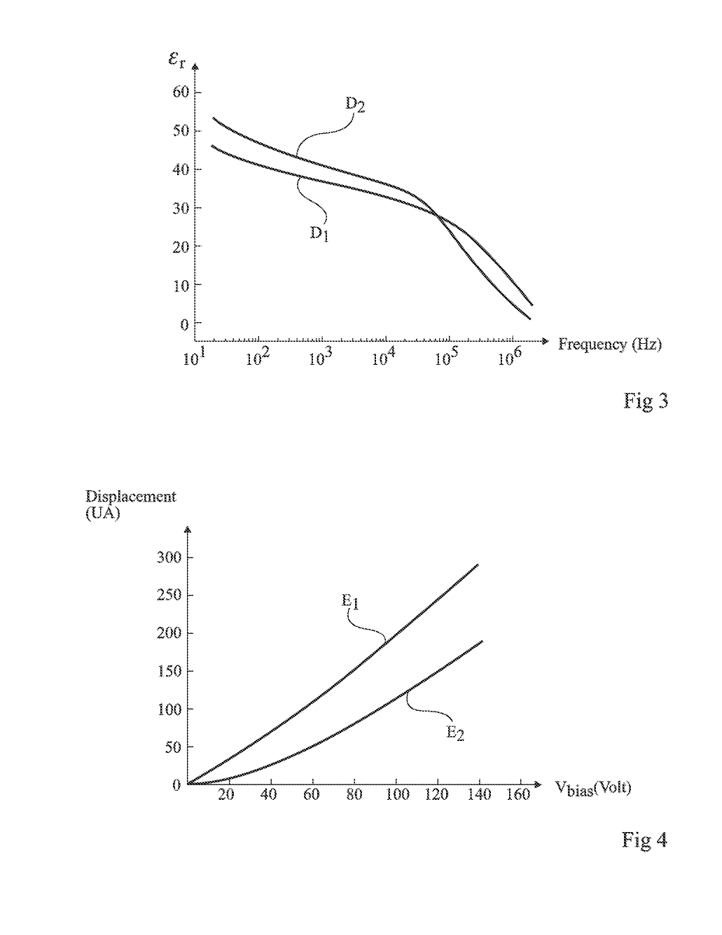

FIG. 3 shows curves D₁ and D₂ of the variation of relative dielectric permittivity εᵣ, also called dielectric constant, respectively of the comparison film and of the test film according to frequency. The measurement of relative dielectric permittivity εr has been performed by placing each film between two electrodes having a sinusoidal voltage applied thereto. Relative dielectric permittivity εᵣ of the test film is greater than the relative dielectric permittivity of the comparison film for frequencies smaller than 5.10⁴ Hz. In particular, for frequencies smaller than 100 Hz, the relative dielectric permittivity increase is at least 15%. For P(VDF-TrFE-CTFE), the dielectric constant at less than 10 Hz is greater than or equal to 55. For P(VDF-TrFE-CFE), the dielectric constant at less than 10 Hz is greater than or equal to 65.

The inventors have highlighted an increase in the piezoelectric and/or pyroelectric activity of a comparison film with respect to the test film.

FIG. 4 shows curves E₁ and E₂ of variation of the displacement, expressed in arbitrary units, respectively of the comparison film and of the test film according to the voltage applied to the film. The displacement has been measured by placing each film between two electrodes having the control voltage applied therebetween. The inventors have shown an increase by more than 50% in the displacement of the test film with respect to the comparison film.

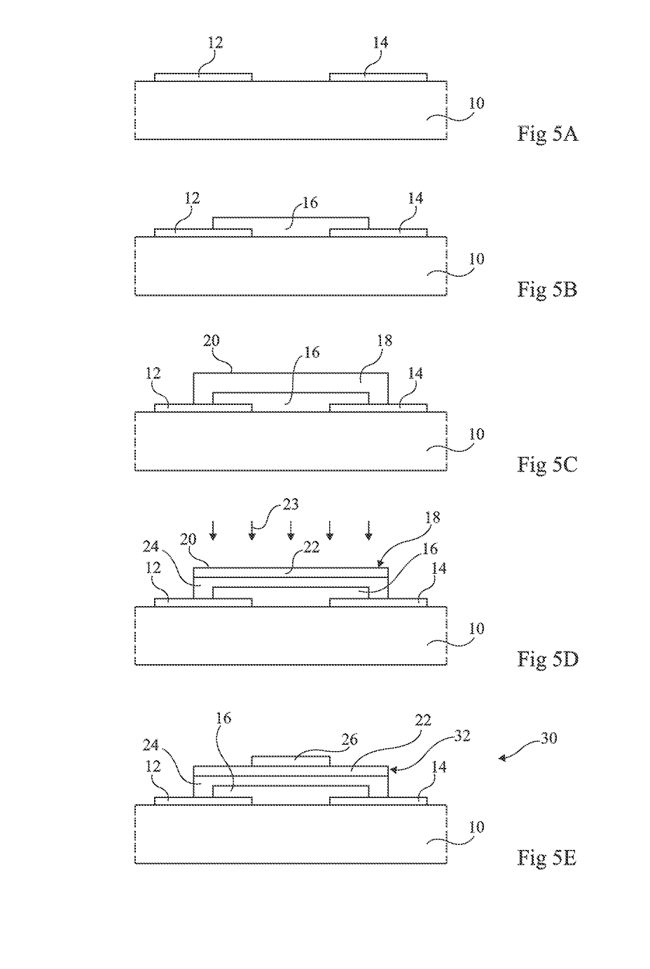

FIGS. 5A to 5E illustrate an embodiment of a method of manufacturing an electronic device comprising a MOS transistor having its gate insulator formed by a film of a PVDF copolymer.

FIG. 5A is a partial simplified cross-section view of the structure obtained after having formed, on a substrate 10, first and second electrically-conductive portions 12, 14.

The thickness of substrate 10 may be in the range from 5 μm to 1,000 μm. Substrate 10 may be a rigid substrate or a flexible substrate. A flexible substrate may, under the action of an external force, deform, and particularly bend, without breaking or tearing. An example of a rigid substrate comprises a silicon, germanium, or glass substrate. Preferably, substrate 12 is a flexible film. An example of flexible substrate comprises a film of PEN (polyethylene naphthalate), PET (polyethylene terephthalate), PI (polyimide), or PEEK (polyetheretherketone). Preferably, substrate 10 may have a thickness from 10 μm to 300 μm and may have a flexible behavior.

Each conductive portion 12, 14 may be made of a metallic material selected from the group comprising silver, gold, nickel, platinum, aluminum, titanium, copper, tungsten, or an alloy or mixture of at least two of these metals, or of a conductive polymer, for example, poly(3, 4-ethylene dioxythiophene): poly(styrene sulfonate) (PEDOT: PSS). Each conductive portion 12, 14 may have a thickness in the range from 10 nm to 300 nm. The deposition of conductive portions 12, 14 on substrate 10 may be performed by physical vapor deposition or by printing techniques, particularly by silk screening or by inkjet printing, or by sputtering.

FIG. 5B shows the structure obtained after having formed a semiconductor portion 16 on conductive portions 12, 14. Semiconductor portion 16 has a thickness in the range from 20 nm to 200 nm, preferably from 20 nm to 100 nm. Semiconductor portion 16 may be made of a semiconductor organic material. It may be formed of small organic N-type molecules, particularly perylenes and derivatives thereof, of small P-type organic molecules, particularly pentacenes and derivatives thereof, of P-type polymers, particularly polythiophenes and derivatives thereof, or of N-type polymers, particularly vinylenes, polymers containing azole units, polythiophenes and derivatives thereof.

FIG. 5C shows the structure obtained after having deposited a portion of a liquid portion 18, possibly viscous, on portion 16, and possible on part of conductive portions 12, 14. The portion of liquid layer 18 comprises a solvent and a compound mainly comprising a PVDF copolymer dissolved in the solvent. The thickness of portion 18 is in the range from 100 nm to 8 μm, preferably from 100 nm to 5 μm. Portion 18 comprises a surface 20 on the side opposite to semiconductor portion 16.

The PVDF copolymer comprises P(VDF-TrFE-CFE), P(VDF-TrFE-CTFE), or a mixture of these compounds. The molecular rate of chlorine in the copolymer is greater than or equal to 3%, preferably greater than or equal to 4%.

The compound may further comprise fillers. The fillers may correspond to ceramic particles, for example, barium titanate particles (BaPiO₃), lead zirconate titanate particles (PbZrTiO₃ or PZT), lead titanate particles (PbTiO₃), or lithium tantalate particles (LiTaO₃). The concentration by weight of fillers in the compound with respect to the mass of the PVDF copolymer may vary from 5% to 25%.

The compound may thus comprise a mixture of at least one PVDF copolymer and of at least one ceramic, for example, the following mixtures: P(VDF-TrFE-CTFE)/BaTiO₃, P(VDF-TrFE-CFE)/BaTiO₃, P(VDF-TrFE-CTFE)/PbZrTiO₃, P(VDF-TrFE-CFE)/PbZrTiO₃, P(VDF-TrFE-CTFE)/PbTiO₃, P(VDF-TrFE-CFE)/PbTiO₃, P(VDF-TrFE-CTFE)/LiTaO₃, and P(VDF-TrFE-CFE)/LiTaO₃.

Preferably, the solvent is a polar solvent. This advantageously enables to improve the dissolution of the PVDF copolymer. Preferably, the solvent is capable of absorbing, at least partially, the UV radiation, for example, over a wavelength range between 200 nm and 400 nm. According to an embodiment, the evaporation temperature of the solvent is in the range from 110° C. to 140° C., preferably from 110° C. to 130° C., more preferably from 120° C. to 130° C. The solvent may be selected from the group comprising cyclopentanone, dimethylsulphoxide (DMSO), dimethylformamide (DMF), gamma-butyrolactone (GBL), methylethylketone (MEK), acetone, dimethylacetamide (DMAc), and N-methyl-E-pyrrolidone (NMP). Preferably, the solvent is cyclopentanone.

Portion 18 comprises from 1% to 30%, preferably from 1% to 20%, by weight of the compound mainly comprising the PVDF copolymer, and from 70% to 99%, preferably from 80% to 99%, by weight of the solvent. Advantageously, the concentration by weight of the solvent is selected to adjust the viscosity of the obtained solution to enable to implement printing techniques. The method of forming liquid layer portion 18 may correspond to a so-called additive process, for example, by direct printing of portion 18 at the desired locations, for example, by inkjet printing, photogravure, silk-screening, flexography, spray coating, or drop casting. The method of forming liquid layer portion 18 may correspond to a so-called subtractive process, where the liquid layer is deposited all over the structure and where the non-used portions are then removed, for example, by photolithography or laser ablation. According to the considered material, the deposition over the entire structure may be performed, for example, by liquid deposition, by cathode sputtering, or by evaporation. Methods such as spin coating, spray coating, heliography, slot-die coating, blade coating, flexography, or silk-screening, may in particular be used.

FIG. 5D illustrates at step of irradiating at least part of portion 18 on the side of surface 20, which causes the forming at the surface of portion 18 of a layer 22 comprising the PVDF copolymer substantially comprising crystals having the same crystal orientation, the rest of portion 18 covered with layer 22 being substantially unmodified. The UV irradiation is schematically shown in FIG. 5D by arrows 23. The irradiation is carried out by a succession of UV radiation pulses, or ultraviolet flashes, which have the previously-described characteristics. The final thickness of layer 22 depends, in particular, on the number of UV pulses and on the composition of portion 18. According to an embodiment, the entire portion 18 may be modified during the irradiation step. As an example, for a 100-nm thickness of layer 22, the number of UV pulses may vary from 1 to 2 with a fluence between 10 J/cm² and 15 J/cm² and for a thickness of layer 22 in the order of 4 μm, the number of UV pulses may be in the range from 2 to 6 with a fluence between 17 J/cm² and 21 J/cm².

Advantageously, the solvent of liquid layer portion 18 at least partly absorbs the UV radiation. This enables to improve the UV-based heating of the compound and to favor the forming of the β crystalline phase. The evaporation temperature of the solvent is advantageously greater than 110° C. to avoid too fast an evaporation of the solvent before the forming of the β crystalline phase, which occurs between 120° C. and 130° C.

The step of exposing portion 18 to UV pulses may be followed by a thermal anneal step, for example, a step of thermal anneal on a hot plate, for example, at a temperature in the range from 80° C. to 120° C. for a duration in the range from 5 min to 30 min. This step of thermal anneal on a hot plate does not modify the structure of layer 22. Preferably, the irradiation and general thermal anneal step cause an evaporation of more than 50 wt. %, preferably more than 80 wt. %, of the solvent of the layer portion 18.

FIG. 5E shows the structure obtained after having deposited a second conductive portion 26 on layer 22. Conductive portion 26 may have the same composition as conductive portions 12, 14. Conductive portion 26 may have a thickness in the range from 10 nm to 300 nm. The deposition of conductive portion 26 may be performed by a physical vapor deposition or by printing techniques, particularly by silk screening or by inkjet printing, or by sputtering. An anneal step may then be provided, for example, by irradiation of conductive portion 26 with UV pulses having a fluence between 15 J/cm² and 25 J/cm².

A MOS transistor 30 is then obtained. Conductive portion 26 forms the gate of transistor 30. The stack of insulating layers 22 and 24 forms gate insulator 32 of transistor 30. Conductive portions 12 and 14 form the drain and source contacts of transistor 30. The channel of transistor 30 is formed in semiconductor layer 16.

The X-ray diffraction diagram of layer 22 is similar to curve C₂ shown in FIG. 2. The X-ray diffraction diagram of layer 24 is similar to curve C₁ shown in FIG. 1. The dielectric constant of the gate insulator of MOS transistor 30 is thus increased at the contact of gate 26. This advantageously enables to increase the drain current of MOS transistor 30 in the on state. The inventors further have shown that the leakage currents of the MOS transistors are decreased.

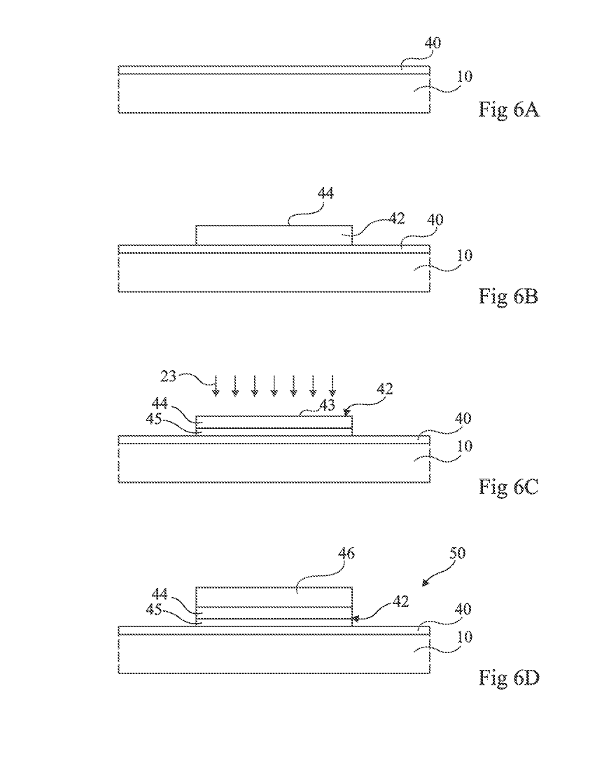

FIGS. 6A to 6D illustrate an embodiment of a method of manufacturing an electronic component having the structure of a metal-oxide-metal capacitor, also called MIM capacitor, and capable of being used, in particular, as a sensor or as an actuator.

FIG. 6A shows the structure obtained after the forming of a conductive portion 40 on substrate 10. The forming of conductive portion 40 may be formed as previously described for the forming of conductive portions 12, 14 in relation with FIG. 5A.

FIG. 6B shows the structure obtained after the forming, on conductive portion 40, of a liquid portion 42, possibly viscous. The portion of liquid layer 42 comprises a solvent and a compound mainly comprising a PVDF copolymer dissolved in the solvent. The composition of portion 42 and the method of depositing portion 42 may correspond to what has been previously described for portion 18 in relation with FIG. 5C. The surface of portion 42 opposite to conductive portion 40 is designated with reference numeral 43.

FIG. 6C shows the structure obtained after the irradiation of portion 42 on the side of surface 43. The method of irradiating portion 42 may correspond to what has been previously described for the irradiation of portion 18 in relation with FIG. 5D. It causes the forming of a layer 44 similar to layer 22 shown in FIG. 5D, having its crystal structure modified by the irradiation, at the surface of portion 42. A general anneal of layer 42 may then be provided to form a layer 45 similar to layer 24 shown in FIG. 5D.

FIG. 6D shows the structure obtained after the forming of a conductive portion 46 on substrate 10. The forming of conductive portion 46 may be formed as previously described for the forming of conductive portion 26 in relation with FIG. 5E.

An electronic component 50 having the structure of a MIM capacitor is then obtained. Conductive portions 40 and 46 form the electrodes of the electronic component. The X-ray diffraction diagram of layer 44 is similar to curve C₂ shown in FIG. 2. For certain electronic components, in particular for a capacitor, it may be desirable for the entire portion 42 to be modified during the irradiation step. In this case, the step of general thermal anneal of portion 42 is not present and the total duration of the electronic component manufacturing method may be decreased. To form a piezoelectric sensor comprising sensors 44 and 45, it may be desirable for layer 44 to be located on the side of electrode 46 used to perform measurements.

Specific embodiments have been described. Various alterations, modifications, and improvements will readily occur to those skilled in the art.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method of manufacturing an electronic device comprising a film, comprising the steps of:
forming at least one layer of a solution comprising a solvent and a compound comprising a polymer selected from the group comprising poly(vinylidene fluoride-trifluoroethylene-chlorofluoroethylene) (P(VDF-TrFE-CFE)), poly(vinylidene fluoride-trifluoroethylene-chlorotrifluoro-ethylene) (P(VDF-TrFE-CTFE)), and a mixture of these compounds, the molecular rate of chlorine in the copolymer being greater than or equal to 3%; and
irradiating at least the layer with pulses of at least one ultraviolet radiation.

2. The method of claim 1, wherein the ultraviolet radiation is emitted by a source, wherein said layer comprises a surface exposed to ultraviolet radiation and wherein the distance between said surface and the source is in the range from 2 cm to 10 cm.

3. The method of claim 1, wherein the duration of each pulse is in the range from 500 μs to 2 ms.

4. The method of claim 1, wherein the energy fluence of the ultraviolet radiation is in the range from 10 J/cm2 to 25 J/cm².

5. The method of claim 1, wherein only a portion of layer is heated during the irradiation step.

6. The method of claim 5, wherein the irradiation step is followed by a step of thermal anneal of the rest of the layer at a temperature in the range from 80° C. to 120° C.

7. The method of claim 1, wherein the solvent has an evaporation temperature in the range from 110° C. to 140° C.

8. The method of claim 1, wherein the solution comprises from 80 wt. % to 95 wt. % of the solvent and from 5 wt. % to 20 wt. % of the compound.

9. A piezoelectric and/or pyroelectric device comprising a layer mainly comprising a partly crystallized polymer selected from the group comprising poly(vinylidene fluoride-trifluoroethylene-chlorofluoroethylene) (P(VDF-TrFE-CTFE)), poly(vinylidene fluoride-trifluoroethylene-chlorotrifluoroethylene) (P(VDF-TrFE-CTFE)) and a mixture of these compounds, the molecular rate of chlorine in the copolymer being greater than or equal to 3%, wherein on at least a portion of the thickness of the layer, the crystal phase(s) of the polymer have the same crystal orientation.

10. The device of claim 9, wherein the layer comprises a first crystallized sub-layer of said polymer where the crystal phase(s) of the polymer have the same crystal orientation and a second sub-layer of said polymer covered with the first sub-layer and in contact with the first sub-layer where the crystal phase(s) of the polymer have different crystal orientations.
